(19) United States
(12) Patent Application Publication
(10) Pub. No.: US 2025/0377697 A1
(43) Pub. Date: Dec. 11, 2025

(54) DISPLAY DEVICE

(71) Applicant: Samsung Display Co., LTD., Yongin-si (KR)

(72) Inventors: Jun Geun LEE, Yongin-si (KR); Jae Chun PARK, Yongin-si (KR); Jun Su LEE, Yongin-si (KR)

(21) Appl. No.: 19/021,503

(22) Filed: Jan. 15, 2025

(30) Foreign Application Priority Data
Jun. 5, 2024 (KR) 10-2024-0073454

(51) Int. Cl. G06F 1/16; H10K 59/127

(52) U.S. Cl. CPC G06F 1/1658; H10K 59/1275

(57) ABSTRACT

A display device includes a display panel, a circuit board electrically connected to the display panel, a connector assembly electrically connected to the circuit board, and a reinforcing member disposed on the circuit board, where the reinforcing member includes a reinforcing film extending from one surface of the circuit board to one surface of the connector assembly, and an anti-bending portion extending from one surface of the reinforcing film in a direction crossing a direction in which the reinforcing film extends.

This application claims priority to Korean Patent Application No. 10-2024-0073454, filed on Jun. 5, 2024, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

An organic light emitting display device has desired characteristics in luminance, driving voltage and response speed, and being able to be subjected to multi-colorization. In this respect, the organic light emitting display device has been applied to various products in various fields. The organic light emitting display device includes a display panel that includes an organic light emitting element. In the organic light emitting element, a cathode electrode and an anode electrode may be disposed around an organic light emitting layer, and when a voltage is applied to the cathode electrode and the anode electrode, visible light is generated in the organic light emitting layer connected to both electrodes.

The organic light emitting display device may include a connector assembly for being connected to inspection equipment for driving inspection of the display panel. The connector assembly may include a connection connector connected to a circuit board, an inspection connector connected to the inspection equipment, and a flexible film connecting the connection connector with the inspection connector.

### BRIEF SUMMARY

Embodiments of the disclosure provide a display device that may prevent a connector assembly from being sagged.

According to an embodiment of the disclosure, a display device includes a display panel, a circuit board electrically connected to the display panel, a connector assembly electrically connected to the circuit board, and a reinforcing member disposed on the circuit board, where the reinforcing member includes a reinforcing film extended from one surface of the circuit board to one surface of the connector assembly, and an anti-bending portion extending from one surface of the reinforcing film in a direction crossing a direction in which the reinforcing film extends.

In an embodiment, the anti-bending portion may extend in a direction orthogonal to the direction in which the reinforcing film extends.

In an embodiment, the anti-bending portion may be folded based on a boundary line between the reinforcing film and the anti-bending portion.

In an embodiment, the anti-bending portion may be folded to overlap the reinforcing film.

In an embodiment, the anti-bending portion may include a first anti-bending portion folded based on a first boundary line, and a second anti-bending portion folded based on a second boundary line crossing the first boundary line.

In an embodiment, the first boundary line and the second boundary line may be defined along one edge of the reinforcing film.

In an embodiment, the anti-bending portion may include a first anti-bending portion and a second anti-bending portion, the first anti-bending portion may extend from one edge of one surface of the reinforcing film, and the second anti-bending portion may extend from an opposing other edge of one surface of the reinforcing film.

In an embodiment, the first anti-bending portion may be disposed along the one edge of the one surface of the reinforcing film, and the second anti-bending portion may be disposed along the opposing edge of the one surface of the reinforcing film.

In an embodiment, the first anti-bending portion and the second anti-bending portion may be disposed in parallel with each other.

In an embodiment, the first anti-bending portion may extend toward an opposing side of the reinforcing film, and the second anti-bending portion may extend toward one side of the reinforcing film.

In an embodiment, an extended end portion of the first anti-bending portion and an extended end portion of the second anti-bending portion may overlap each other.

In an embodiment, a portion where an extended end portion of the first anti-bending portion and an extended end portion of the second anti-bending portion overlap each other may be spaced apart from the one surface of the reinforcing film.

In an embodiment, the extended end portion of the first anti-bending portion and the extended end portion of the second anti-bending portion may be in contact with each other, and a fastening portion, which fastens the extended end portion of the first anti-bending portion and the extended end portion of the second anti-bending portion to each other, may be disposed at a portion where the extended end portion of the first anti-bending portion and the extended end portion of the second anti-bending portion are in contact each other.

According to an embodiment of the disclosure, a display device includes a display panel, a circuit board electrically connected to the display panel, where the circuit board includes a connection terminal, a connector assembly including a connection connector connected to the connection terminal and an inspection connector connected to the connection connector, and a reinforcing member disposed on the circuit board, where the reinforcing member includes a reinforcing film disposed on one surface of the circuit board and one surface of the inspection connector, and an anti-bending portion disposed on one surface of the reinforcing film and extending from the one surface of the circuit board to the one surface of the inspection connector.

In an embodiment, the anti-bending portion may extend from the one surface of the reinforcing film in a thickness direction of the reinforcing film.

In an embodiment, the anti-bending portion is may be folded based on a boundary line between the reinforcing film and the anti-bending portion.

In an embodiment, the anti-bending portion may be folded to overlap the reinforcing film.

In an embodiment, the anti-bending portion may include a first anti-bending portion folded based on a first boundary line, and a second anti-bending portion folded based on a second boundary line crossing the first boundary line.

In an embodiment, the anti-bending portion may include a first anti-bending portion and a second anti-bending portion, the first anti-bending portion may extend from one edge of the one surface of the reinforcing film, and the second anti-bending portion may extend from an opposing edge of the one surface of the reinforcing film.

In an embodiment, the first anti-bending portion may extend toward an opposing side of the reinforcing film, the second anti-bending portion may extend toward one side of the reinforcing film, and an extended end portion of the first anti-bending portion and an extended end portion of the second anti-bending portion may overlap each other, or may be in contact with each other.

According to embodiments of the display device of the disclosure, a reinforcing member may be disposed on one surface of a circuit board and one surface of a connector assembly, and may be formed to be partially folded, such that the connector assembly may be effectively prevented from being sagged.

The effects according to the embodiments of the disclosure are not limited to those mentioned above and more various effects are included in the following description of the disclosure.

### BRIEF DESCRIPTION OF THE DRAWINGS

The above and other features of embodiments of the disclosure will become more apparent by describing in detail embodiments thereof with reference to the attached drawings, in which:

FIG. 1 is a plan view illustrating a state that a connection member of a display device according to an embodiment of the disclosure is unfolded;

FIG. 2 is a plan view illustrating a state that a connection member of a display device according to an embodiment of the disclosure is folded;

FIG. 3 is a cross-sectional view taken along line A-A′ of FIG. 2;

FIG. 4 is a schematic cross-sectional view illustrating a display panel of FIG. 3;

FIG. 5 is a plan view illustrating a circuit board of FIG. 1;

FIG. 6 is a plan view illustrating a connector assembly and a reinforcing member of FIG. 1;

FIG. 7 is a plan view illustrating a state that a circuit board, a connector assembly and a reinforcing member of FIG. 1 are connected;

FIGS. 8 and 9 are perspective views illustrating a state that a circuit board, a connector assembly and a reinforcing member of a display device according to an embodiment of the disclosure are connected;

FIG. 10 is a perspective view illustrating a state that a circuit board, a connector assembly and a reinforcing member of a display device according to another embodiment of the disclosure are connected;

FIG. 11 is a perspective view illustrating a state that a circuit board, a connector assembly and a reinforcing member of a display device according to another embodiment of the disclosure are connected; and

FIGS. 12 and 13 are perspective views illustrating a state that a circuit board, a connector assembly and a reinforcing member of a display device according to another embodiment of the disclosure are connected.

FIG. 14 is a block diagram of an electronic device according to one embodiment of the present disclosure.

FIG. 15 is a schematic diagram of an electronic device according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

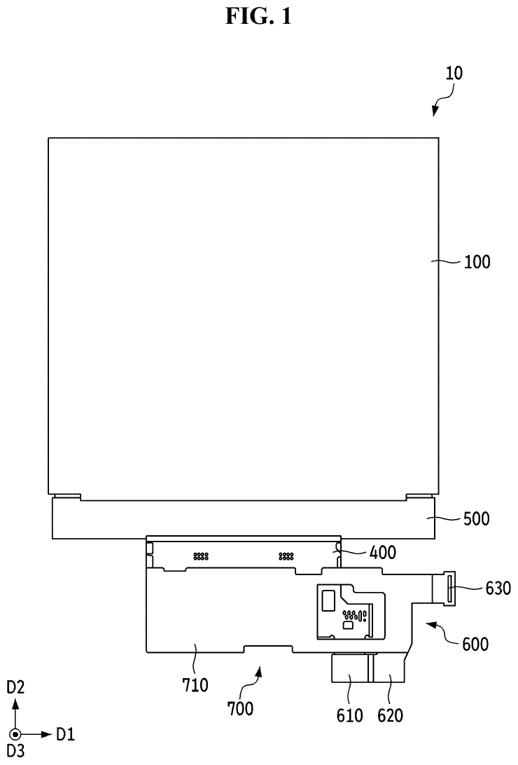

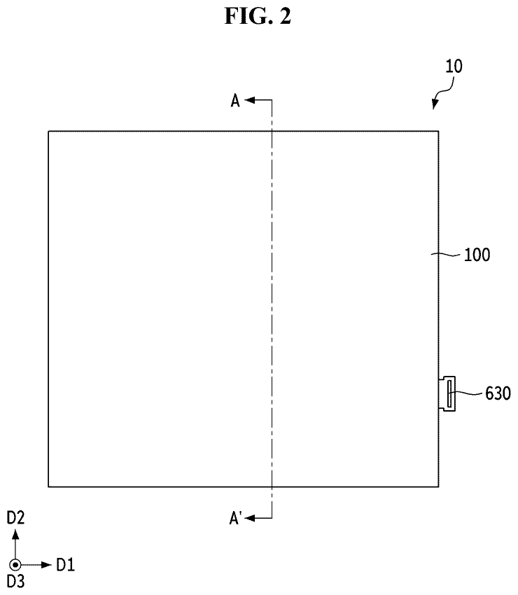

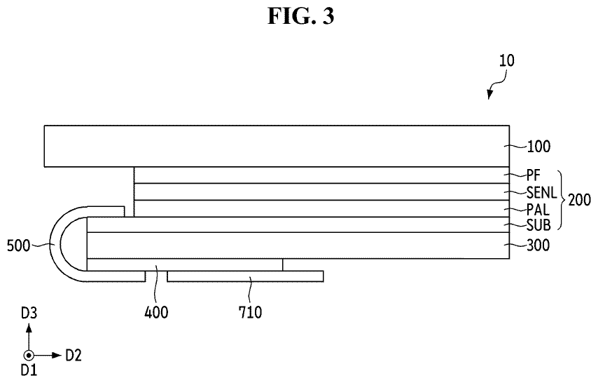

FIG. 1 is a plan view illustrating a state that a connection member 500 of a display device 10 according to an embodiment of the disclosure is unfolded. FIG. 2 is a plan view illustrating that a connection member 500 of a display device 10 according to an embodiment of the disclosure is folded. FIG. 3 is a cross-sectional view taken along line A-A′ of FIG. 2.

The display device 10 according to an embodiment of the disclosure is a device that displays a moving image or a still image, and may be used as a display screen of various products such as a television, a laptop computer, a monitor, an advertising board and a device for Internet of things (IoT) as well as portable electronic devices such as a mobile phone, a smart phone, a tablet personal computer (PC), a smart watch, a watch phone, a mobile communication terminal, an electronic diary, an electronic book, a portable multimedia player (PMP), a navigator and an ultra mobile PC (UMPC). Alternatively, the display device 10 may be used as a display screen of a various product, e.g., a display screen applied to a center fascia of a vehicle. Hereinafter, for convenience of description, embodiments where the display device 10 is a smart phone will be mainly described, but the disclosure is not limited thereto.

The display device 10 may be an organic light emitting display device including an organic light emitting diode, a quantum dot light emitting display device including a quantum dot light emitting layer, an inorganic light emitting display device including an inorganic semiconductor, or a micro light emitting display device using a micro light emitting diode. Hereinafter, for convenience of description, embodiments where the display device 10 is an organic light emitting display device will be mainly described, but the disclosure is not limited thereto.

Referring to FIGS. 1 to 3, the display device 10 according to an embodiment of the disclosure may include a cover window 100, a display panel 200, a panel lower member 300, a circuit board 400, a connection member 500, a connector assembly 600 and a reinforcing member 700.

The cover window 100 may be disposed on an upper portion of the display panel 200 to cover an upper surface of the display panel 200. The cover window 100 may serve to protect the upper surface of the display panel 200. The cover window 100 may include a transmissive portion for transmitting light and a light blocking portion for blocking light.

The cover window 100 may include a material having high light transmittance. The cover window 100 may include a polymer resin such as polyimide or glass. The cover window 100 may be attached onto a polarizing film PF, which will be described later, of the display panel 200 by an adhesive member such as an optically clear adhesive (OCA) film.

The display panel 200 may be disposed below the cover window 100. In an embodiment, the display panel 200 may have a rectangular plane shape having a side in a first direction D1 and a side in a second direction D2 when viewed in a plan view or in a third direction D3. Here, D3 may be a direction perpendicular to the first direction D1 and the second direction D2, or be a thickness direction of the display panel 200. In the display panel 200, a corner at which the side in the first direction D1 and the side in the second direction D2 meet may be formed at a right angle, or may be rounded to have a predetermined curvature. In another embodiment, the display panel 200 may have another polygonal shape, for example, a circular shape, an oval shape or an irregular plane shape.

The display panel 200 may include a display area in which a plurality of light emission areas for emitting light are disposed and a non-display area disposed around the display area. The non-display area may be disposed to surround the display area. A plurality of display pads may be disposed in the non-display area at an edge portion of one side of the display panel 200.

In an embodiment, as shown in FIG. 3, the display panel 200 may include a substrate SUB, a display unit PAL, a sensor unit SENL and a polarizing film PF.

The substrate SUB may include or be made of an insulating material such as glass, quartz and a polymer resin. The substrate SUB may be a rigid substrate, or may be a flexible substrate capable of being subjected to bending, folding, rolling, etc.

The display unit PAL may be disposed on the substrate SUB. The display unit PAL may be a layer that includes a plurality of light emission areas for emitting light. The display unit PAL may include a buffer film, a thin film transistor layer in which thin film transistors are disposed, a light emitting element layer for emitting light, and an encapsulation layer for encapsulating the light emitting element layer.

The sensor unit SENL may be disposed on the display unit PAL. The sensor unit SENL includes sensor electrodes, and may be a layer for sensing whether there is a user's touch.

The polarizing film PF may be disposed on the sensor unit SENL. The polarizing film PF may serve to prevent deterioration in image visibility of the display panel 200 due to reflection of external light. The polarizing film PF may include a linearly polarizing plate and a phase delay film such as a λ/4 (quarter-wave) plate. The phase delay film may be disposed on the sensor unit SENL, and the linearly polarizing plate may be disposed on the phase delay film. The cover window 100 may be disposed on the polarizing film PF.

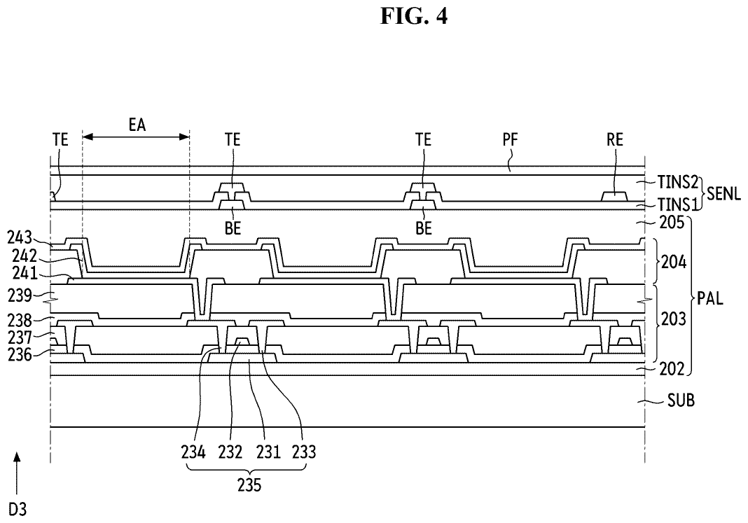

FIG. 4 is a schematic cross-sectional view illustrating the display panel 200 of FIG. 3.

Referring to FIG. 4, in an embodiment, the display unit PAL may include a buffer film 202, a thin film transistor layer 203, a light emitting element layer 204 and an encapsulation layer 205.

The buffer film 202 may be disposed on the substrate SUB. The buffer film 202 may be disposed on the substrate SUB to protect thin film transistors 235 and light emitting elements from moisture permeated through the substrate SUB that is vulnerable to moisture permeation. The buffer film 202 may be formed of (or defined by) a plurality of inorganic films that are alternately stacked. In an embodiment, for example, the buffer film 202 may be formed of a multi-film in which one or more inorganic films of a silicon oxide film (SiOx), a silicon nitride film (SiNx) and SiON are alternately stacked. In another embodiment, the buffer film 202 may be omitted.

The thin film transistor layer 203 is disposed on the buffer film 202. The thin film transistor layer 203 includes the thin film transistors 235, a gate insulating film 236, an interlayer insulating film 237, a passivation film 238 and an organic film 239.

Each of the thin film transistors 235 includes an active layer 231, a gate electrode 232, a source electrode 233 and a drain electrode 234. Although FIG. 4 illustrates an embodiment where the thin film transistors 235 are formed in a top gate mode in which the gate electrode 232 is positioned above the active layer 231, it should be noted that the thin film transistors 235 are not limited thereto. In another embodiment, the thin film transistors 235 may be formed in a bottom gate mode in which the gate electrode 232 is positioned below the active layer 231 or a double gate mode in which the gate electrode 232 is positioned above and below the active layer 231.

The active layer 231 is disposed on the buffer film 202. The active layer 231 may include or be formed of a silicon-based semiconductor material or an oxide-based semiconductor material. In an embodiment, for example, the active layer 231 may include or be formed of polysilicon, amorphous silicon or an oxide semiconductor. A light blocking layer for blocking external light incident on the active layer 231 may be disposed between the buffer film 202 and the active layer 231.

The gate insulating film 236 may be disposed on the active layer 231. The gate insulating film 236 may include or be formed of an inorganic film, for example, a silicon oxide film (SiOx), a silicon nitride film (SiNx) or a multi-film thereof.

The gate electrode 232 may include or be formed on the gate insulating film 236. The gate electrode 232 and a gate line may include or be formed of a single layer or multi-layer, each layer therein including at least one selected from molybdenum (Mo), aluminum (Al), chromium (Cr), gold (Au), titanium (Ti), nickel (Ni), neodymium (Nd) and copper (Cu), or their alloy.

The interlayer insulating film 237 may be disposed on the gate electrode 232 and the gate line. The interlayer insulating film 237 may include or be formed of an inorganic film, for example, a silicon oxide film (SiOx), a silicon nitride film (SiNx) or their multi-film.

The source electrode 233 and the drain electrode 234 may be disposed on the interlayer insulating film 237. Each of the source electrode 233 and the drain electrode 234 may be connected to the active layer 231 through a contact hole defined through the gate insulating film 236 and the interlayer insulating film 237. The source electrode 233 and the drain electrode 234 may include or be formed of a single layer or multi-layer, each layer therein including at least one selected from molybdenum (Mo), aluminum (Al), chromium (Cr), gold (Au), titanium (Ti), nickel (Ni), neodymium (Nd) and copper (Cu), or their alloy.

The passivation film 238 for insulating the thin film transistor 235 may be disposed on the source electrode 233 and the drain electrode 234. The passivation film 238 may include or be formed of an inorganic film, for example, a silicon oxide film (SiOx), a silicon nitride film (SiNx) or their multi-film.

The organic film 239 for planarizing a step difference due to the thin film transistor 235 may be disposed on the passivation film 238. The organic film 239 may include or be formed of an organic film such as an acrylic resin, an epoxy resin, a phenolic resin, a polyamide resin or a polyimide resin.

The light emitting element layer 204 is disposed on the thin film transistor layer 203. The light emitting element layer 204 includes light emitting elements and a bank.

The light emitting elements and the bank are disposed on the organic film 239. The light emitting element may be an organic light emitting element that includes an anode electrode 241, light emitting layers 242 and a cathode electrode 243.

The anode electrode 241 may be disposed on the organic film 239. The anode electrode 241 may be connected to the source electrode 233 of the thin film transistor 235 through a contact hole defined through the passivation film 238 and the organic film 239.

The bank may be disposed to cover an edge of the anode electrode 241 on the organic film 239 to partition light emission areas EA of pixels. That is, the bank serves to define the light emission areas EA of the pixels. Each of the pixels represents an area in which the anode electrode 241, the light emitting layer 242 and the cathode electrode 243 are sequentially stacked to combine holes from the anode electrode 241 with electrons from the cathode electrode 243 in the light emitting layer 242, thereby emitting light.

The light emitting layers 242 are disposed on the anode electrode 241 and the bank. The light emitting layer 242 may be an organic light emitting layer. The light emitting layer 242 may emit one of red light, green light and blue light. Alternatively, the light emitting layer 242 may be a white light emitting layer for emitting white light, and in this case, the light emitting layer 242 may have a structure in which the red light emitting layer, the green light emitting layer and the blue light emitting layer are stacked, and may be a common layer commonly formed in the pixels. In this case, the display panel 200 may further include a separate color filter for displaying red, green and blue.

The light emitting layer 242 may include a hole transporting layer, a light emitting layer and an electron transporting layer. In addition, the light emitting layer 242 may be formed in a tandem structure of two or more stacks, and in this case, a charge generating layer may be formed between the stacks.

The cathode electrode 243 is disposed on the light emitting layer 242. The cathode electrode 243 may be disposed to cover the light emitting layer 242. The cathode electrode 243 may be a common layer commonly formed in the pixels.

In an embodiment where the light emitting element layer 204 is formed in a top emission mode in which light is emitted in an upward direction, the anode electrode 241 may include or be formed of a metal material having high reflectance, such as a stacked structure (Ti/Al/Ti) of aluminum (Al) and titanium (Ti), a stacked structure (ITO/Al/ITO) of aluminum (Al) and indium tin oxide (ITO), APC alloy and a stacked structure (ITO/APC/ITO) of APC alloy and ITO. The APC alloy is an alloy of silver (Ag), palladium (Pd) and copper (Cu). The cathode electrode 243 may include or be formed of a transparent conductive material TCO such as ITO and IZO, which may transmit light, or a semi-transmissive conductive material such as magnesium (Mg), silver (Ag) or an alloy of magnesium (Mg) and silver (Ag). In an embodiment where the cathode electrode 243 includes or is formed of a semi-transmissive conductive material, light emission efficiency may be increased by a micro cavity.

In an embodiment where the light emitting element layer 204 is formed in a bottom emission mode in which light is emitted in a downward direction, the anode electrode 241 may be formed of a metal material having high reflectance, such as a stacked structure (Ti/Al/Ti) of aluminum (Al) and titanium (Ti), a stacked structure (ITO/AI/ITO) of aluminum (Al) and indium tin oxide (ITO), APC alloy and a stacked structure (ITO/APC/ITO) of APC alloy and ITO. The cathode electrode 243 may include or be formed of a metal material having high reflectance, such as a stacked structure (Ti/Al/Ti) of aluminum (Al) and titanium (Ti), a stacked structure (ITO/Al/ITO) of aluminum (Al) and ITO, APC alloy, and a stacked structure (ITO/APC/ITO) of APC alloy and ITO. In an embodiment where the anode electrode 241 is formed of a semi-transmissive conductive material, light emission efficiency may be increased by a micro cavity.

The encapsulation layer 205 is disposed on the light emitting element layer 204. The encapsulation layer 205 serves to prevent permeation of oxygen or moisture into the light emitting layer 242 and the cathode electrode 243. In such an embodiment, the encapsulation layer 205 may include at least one inorganic film. The inorganic film may include or be formed of silicon nitride, aluminum nitride, zirconium nitride, titanium nitride, hafnium nitride, tantalum nitride, silicon oxide, aluminum oxide or titanium oxide. Also, the encapsulation layer 205 may further include at least one organic film. The organic film may be formed to have a sufficient thickness to prevent particles from being permeated into the light emitting layer 242 and the cathode electrode 243 by passing through the encapsulation layer 205. The organic film may include at least one selected from epoxy, acrylate and urethane acrylate.

The sensor unit SENL may be disposed on the encapsulation layer 205. In an embodiment where the sensor unit SENL is formed directly on the encapsulation layer 205, a thickness of the display device 10 may be reduced as compared with the case that a separate touch panel is attached onto the encapsulation layer 205.

The sensor unit SENL may include sensor electrodes for sensing a user's touch in a capacitance manner and touch lines connecting pads with the sensor electrodes. In an embodiment, for example, the sensor unit SENL may sense a user's touch in a self-capacitance manner or a mutual capacitance manner. FIG. 4 shows an embodiment where the sensor unit SENL is formed in a mutual capacitance manner of a two-layer that includes the driving electrodes TE, the sensing electrodes RE, and the connection portions BE connecting the driving electrodes TE.

The connection portions BE may be disposed on the encapsulation layer 205. The connection portions BE may be formed of a stacked structure (Ti/Al/Ti) of aluminum and titanium, a stacked structure (ITO/Al/ITO) of aluminum (Al) and ITO, APC alloy, and a stacked structure (ITO/APC/ITO) of APC alloy and ITO, but are not limited thereto. In an embodiment, for example, the connection portions BE may be formed of a single layer of molybdenum (Mo), titanium (Ti), copper (Cu), aluminum (Al) or ITO.

A first sensing insulating film TINS1 is disposed on the connection portions BE. The first sensing insulating film TINS1 may be formed of an inorganic film, for example, a silicon nitride layer, a silicon oxynitride layer, a silicon oxide layer, a titanium oxide layer or an aluminum oxide layer.

The driving electrodes TE and the sensing electrodes RE may be disposed on the first sensing insulating film TINS1. The driving electrodes TE and the sensing electrodes RE may be formed of a stacked structure (Ti/Al/Ti) of aluminum (Al) and titanium, a stacked structure (ITO/AI/ITO) of aluminum (Al) and ITO, APC alloy, and a stacked structure (ITO/APC/ITO) of APC alloy and ITO, but are not limited thereto. In an embodiment, for example, the driving electrodes TE and the sensing electrodes RE may be formed of a single layer of molybdenum (Mo), titanium (Ti), copper (Cu), aluminum (Al) or ITO.

Contact holes exposing the connection portions BE by passing through the first sensing insulating film TINS1 may be defined or formed in the first sensing insulating film TINS1. The driving electrodes TE may be connected to the connection portions BEs through the contact holes.

A second sensing insulating film TINS2 is disposed on the driving electrodes TE and the sensing electrodes RE. The second sensing insulating film TINS2 may serve to planarize a step difference caused by the driving electrodes TE, the sensing electrodes RE and the connection portions BE. The second sensing insulating film TINS2 may include or be formed of an organic film including an organic material such as an acrylic resin, an epoxy resin, a phenolic resin, a polyamide resin or a polyimide resin.

The connection portions BE connecting the driving electrodes TE adjacent to each other may be disposed on the encapsulation layer 205, and the driving electrodes TE and the sensing electrodes RE may be disposed on the first sensing insulating film TINS1. Therefore, the driving electrodes TE and the sensing electrodes RE may be electrically separated from each other at their intersections, the sensing electrodes RE may be electrically connected to each other in one direction, and the driving electrodes TE may be electrically connected to each other in the other direction.

The panel lower member 300 may be disposed below the substrate SUB. The panel lower member 300 may be attached to a lower surface of the substrate SUB through an adhesive member. The adhesive member may be a pressure sensitive adhesive (PSA). The panel lower member 300 may include at least one selected from a light absorbing member for absorbing light incident from the outside, a buffer member for absorbing impact from the outside, and a heat dissipating member for efficiently dissipating heat from the display panel 200.

The light absorbing member may be disposed below the substrate SUB. The light absorbing member blocks transmission of light to prevent components disposed below the light absorbing member, for example, the circuit board 400, from being visually recognized from the top of the display panel 200. The light absorbing member may include a light absorbing material such as a black pigment or a black dye.

The buffer member may be disposed below the light absorbing member. The buffer member absorbs an external impact to prevent the display panel 200 from being damaged. The buffer member may be formed of a single layer or a plurality of layers. In an embodiment, for example, the buffer member may include or be formed of a polymer resin such as polyurethane, polycarbonate, polypropylene and polyethylene, or may include a material having elasticity such as rubber, a urethane-based material or a sponge obtained by foaming an acrylic-based material.

The heat dissipation member may be disposed below the buffer member. The heat dissipation member may include a first heat dissipation layer containing graphite, carbon nanotubes or the like, and a second heat dissipation layer formed of a metal thin film such as copper, nickel, ferrite or silver, which may shield electromagnetic waves and have excellent thermal conductivity.

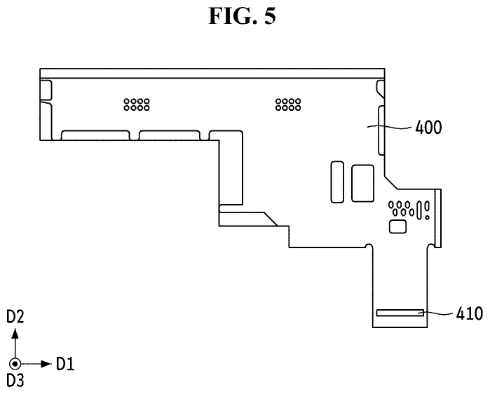

FIG. 5 is a plan view illustrating the circuit board 400 of FIG. 1.

Referring to FIG. 5, in an embodiment, the circuit board 400 may be disposed below the panel lower member 300. The circuit board 400 may be a flexible printed circuit board (FPCB) that may be bent, a rigid printed circuit board (PCB) that is rigid not to be easily bent, or a composite printed circuit board that includes both a rigid printed circuit board and a flexible printed circuit board.

In an embodiment, as shown in FIG. 1, the circuit board 400 may be connected to the display panel 200 by a connection member 500, and a connection terminal 410 for connection with the connector assembly 600 may be disposed at one side of the circuit board 400.

The connection member 500 may be connected to a plurality of display pads of the display panel 200 through a conductive adhesive member such as an anisotropic conductive film. Therefore, the display panel 200 and the connection member 500 may be electrically connected to each other.

In an embodiment, the connection member 500 may be connected to a plurality of circuit pads of the circuit board 400 through a conductive adhesive member such as an anisotropic conductive film. In such an embodiment, the connection member 500 and the circuit board 400 may be electrically connected to each other. In this way, as the connection member 500 is electrically connected to the display panel 200 and the circuit board 400, the display panel 200 may be electrically connected with the circuit board 400.

The connection member 500 may be a flexible printed circuit board, a rigid printed circuit board, a composite printed circuit board that includes both a rigid printed circuit board and a flexible printed circuit board, or a chip on film.

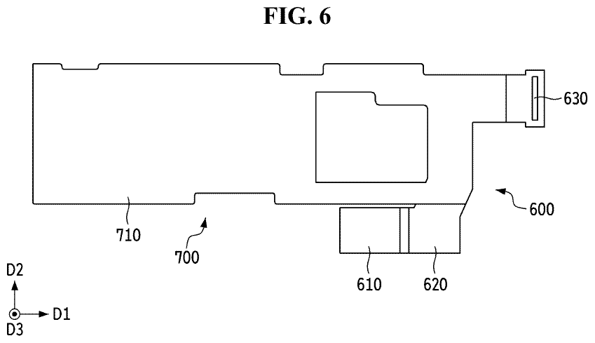

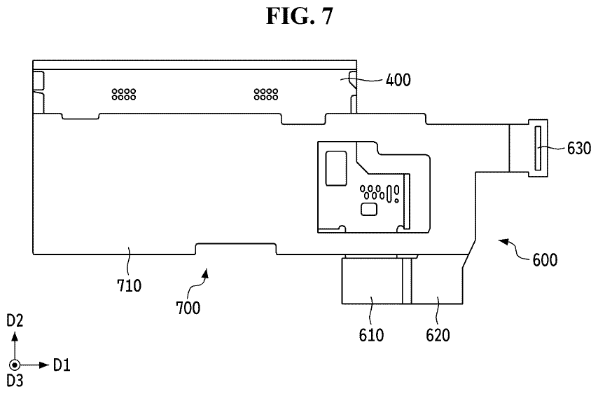

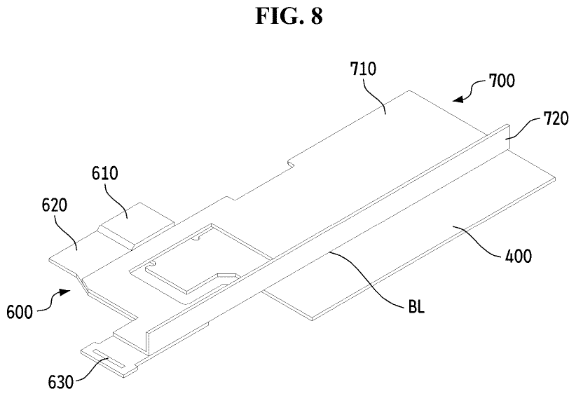

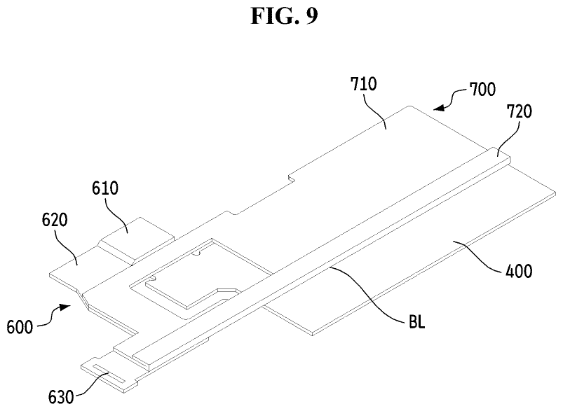

FIG. 6 is a plan view illustrating the connector assembly 600 and the reinforcing member 700 of FIG. 1. FIG. 7 is a plan view illustrating a state that the circuit board 400, the connector assembly 600 and the reinforcing member 700 of FIG. 1 are connected. FIGS. 8 and 9 are perspective views illustrating a state that the circuit board 400, the connector assembly 600 and the reinforcing member 700 of the display device 10 according to an embodiment of the disclosure are connected.

Referring to FIGS. 6 to 9, in an embodiment, the connector assembly 600 may be electrically connected to the circuit board 400. The connector assembly 600 may include a connection connector 610, a flexible film 620 and an inspection connector 630.

The connection connector 610 may be electrically connected to the connection terminal 410 of the circuit board 400. The connection connector 610 may include or be formed of a conductive material and electrically connected to the connection terminal 410 by being in contact with the connection terminal 410. The connection connector 610 may be disposed on one surface of the connection terminal 410.

The flexible film 620 may electrically connect the connection connector 610 to the inspection connector 630. The flexible film 620 may extend from the connection connector 610 in the first direction D1. The flexible film 620 may extend from the connection connector 610 in the first direction D1, may extend in the second direction D2 from an end portion extending in the first direction D2, and may extend in the first direction D1 from an end portion extending in the second direction D2. In other words, an end portion of the flexible film 620, which extends to be bent several times, may be spaced apart from the circuit board 400 in the first direction D1. The inspection connector 630 may be disposed at an end portion of the flexible film 620, which extends toward the first direction D1. The flexible film 620 may be a flexible printed circuit board or a chip on film.

The inspection connector 630 may be connected to an inspection equipment (not shown). The inspection connector 630 may be disposed at the end portion of the flexible film 620, which extends in the first direction D1. The inspection connector 630 may be connected to the connection connector 610 by the flexible film 620, and may be electrically connected to the display panel 200 as the connection connector 610 is connected to the circuit board 400. Since the inspection equipment is connected to the inspection connector 630 electrically connected to the display panel 200, driving inspection of the display panel 200 may be performed.

Since the inspection connector 630 is spaced apart from the circuit board 400 in the first direction D1 and connected to the circuit board 400 by the flexible film 620, sagging of the inspection connector 630 in a third direction D3 may occur.

The reinforcing member 700 may be disposed on one surface of the connector assembly 600 and the circuit board 400 to effectively prevent the inspection connector 630 from being sagged in the third direction D3. In an embodiment, as shown in FIGS. 8 and 9, the reinforcing member 700 may include a reinforcing film 710 and an anti-bending portion 720.

The reinforcing film 710 may be provided as a film having a predetermined thickness, and may be disposed on one surface of the circuit board 400. The reinforcing film 710 may be attached onto one surface of the circuit board 400 through an adhesive material such as an adhesive. The reinforcing film 710 be extend from one surface of the circuit board 400 to one surface of the inspection connector 630. The reinforcing film 710 extending from one surface of the circuit board 400 may extend onto one surface of the inspection connector 630 via one surface of the flexible film 620. The extending portion of the reinforcing film 710 may be attached onto one surface of the flexible film 620 and one surface of the inspection connector 630 through an adhesive material such as an adhesive.

In an embodiment, the anti-bending portion 720 may extend from one surface of the reinforcing film 710 in a direction crossing the direction in which the reinforcing film 710 extends. The anti-bending portion 720 may be provided as a film having a predetermined thickness, and may extend from one surface of the reinforcing film 710 in a thickness direction of the reinforcing film 710. In other words, the anti-bending portion 720 may extend from one surface of the reinforcing film 710 in the third direction D3. The anti-bending portion 720 may be disposed on one surface of the reinforcing film 710, and may extend from one surface of the circuit board 400 to one surface of the inspection connector 630. In other words, the anti-bending portion 720 may extend along one edge of the reinforcing film 710 on one surface of the reinforcing film 710. Since the anti-bending portion 720 extends in a direction orthogonal to the reinforcing film 710, the reinforcing film 710 and the flexible film 620 attached to the reinforcing film 710 may be effectively prevented from being sagged.

In an embodiment, as shown in FIG. 8, the anti-bending portion 720 may be formed to be folded (or bent) based on a boundary line BL that forms a boundary between the reinforcing film 710 and the anti-bending portion 720. In an embodiment, as shown in FIG. 9, the anti-bending portion 720 formed may be (entirely or completely) folded to overlap the reinforcing film 710. The anti-bending portion 720 folded to overlap the reinforcing film 710 may be attached to the reinforcing film 710 through an adhesive material such as an adhesive. Since the anti-bending portion 720 is folded to overlap the reinforcing film 710 and then attached to the reinforcing film 710, the reinforcing film 710 and the flexible film 620 attached to the reinforcing film 710 may be effectively prevented from being sagged.

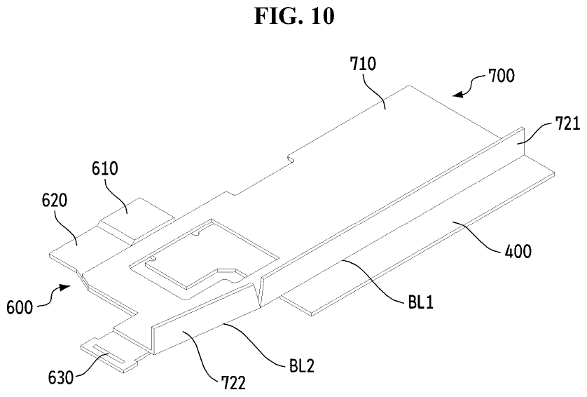

Hereinafter, the display device 10 according to other embodiments of the disclosure will be described with reference to FIGS. 10 to 12. Such embodiments are substantially the same as the embodiments described above except for the reinforcing member 700. The same or like elements shown in FIGS. 10 to 12 are labeled with the same reference characters as used above to describe the embodiments, and any repetitive detailed description thereof will hereinafter be omitted or simplified.

FIG. 10 is a perspective view illustrating a state that the circuit board 400, the connector assembly 600 and the reinforcing member 700 of the display device 10 according to another embodiment of the disclosure are connected.

Referring to FIG. 10, the reinforcing member 700 of the display device 10 according to another embodiment of the disclosure may be disposed on one surface of the connector assembly 600 and the circuit board 400 to effectively prevent the inspection connector 630 from being sagged in the third direction D3. The reinforcing member 700 may include a reinforcing film 710, a first anti-bending portion 721 and a second anti-bending portion 722.

The reinforcing film 710 may be provided as a film having a predetermined thickness, and may be disposed on one surface of the circuit board 400. The reinforcing film 710 may be attached onto one surface of the circuit board 400 through an adhesive material such as an adhesive. The reinforcing film 710 may extend from one surface of the circuit board 400 to one surface of the inspection connector 630. The reinforcing film 710 extending from one surface of the circuit board 400 may extend onto one surface of the inspection connector 630 via one surface of the flexible film 620. The extending portion of reinforcing film 710 may be attached onto one surface of the flexible film 620 and one surface of the inspection connector 630 through an adhesive material such as an adhesive.

The first anti-bending portion 721 may extend from one surface of the reinforcing film 710 in a direction crossing the direction in which the reinforcing film 710 extends. The first anti-bending portion 721 may be provided as a film having a predetermined thickness, and may extend from one surface of the reinforcing film 710 in the thickness direction of the reinforcing film 710. In other words, the first anti-bending portion 721 may extend from one surface of the reinforcing film 710 in the third direction D3. The first anti-bending portion 721 may be disposed on one surface of the reinforcing film 710, and may extend to cross one surface of the circuit board 400. The first anti-bending portion 721 may extend along one edge of the reinforcing film 710 on one surface of the reinforcing film 710.

The first anti-bending portion 721 may be formed to be folded based on a first boundary line BL1 that forms a boundary between the reinforcing film 710 and the first anti-bending portion 721.

The second anti-bending portion 722 may extend from one surface of the reinforcing film 710 in a direction crossing the direction in which the reinforcing film 710 is extended. The second anti-bending portion 722 may be provided as a film having a predetermined thickness, and may extend from one surface of the reinforcing film 710 in the thickness direction of the reinforcing film 710. In other words, the second anti-bending portion 722 may extend from one surface of the reinforcing film 710 in the third direction D3. The second anti-bending portion 722 may be formed subsequently to the first anti-bending portion 721. The second anti-bending portion 722 may extend from an end portion of the first anti-bending portion 721 in the first direction D1 to one surface of the inspection connector 630.

The second anti-bending portion 722 may extend along one edge of the reinforcing film 710 on one surface of the reinforcing film 710.

The second anti-bending portion 722 may be formed to be folded based on a second boundary line BL2 that forms a boundary between the reinforcing film 710 and the second anti-bending portion 722. The second boundary line BL2 may cross the first boundary line BL1. In other words, the second boundary line BL2 may be formed to be bent at a predetermined angle toward the inspection connector 630 from an end portion of the first boundary line BL1 in the first direction D1.

In such an embodiment, since the first anti-bending portion 721 and the second anti-bending portion 722 extends in a direction orthogonal to the reinforcing film 710, the reinforcing film 710 and the flexible film 620 attached to the reinforcing film 710 may be effectively prevented from being sagged.

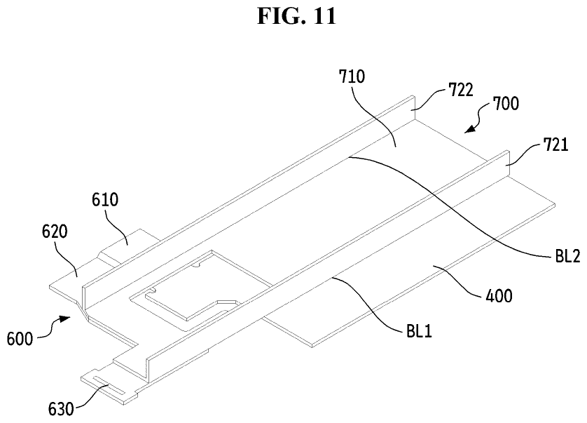

FIG. 11 is a perspective view illustrating a state that the circuit board 400, the connector assembly 600 and the reinforcing member 700 of the display device 10 according to another embodiment of the disclosure are connected.

Referring to FIG. 11, the reinforcing member 700 of the display device 10 according to another embodiment of the disclosure may be disposed on one surface of the connector assembly 600 and the circuit board 400 to effectively prevent the inspection connector 630 from being sagged in the third direction D3. The reinforcing member 700 may include a reinforcing film 710, a first anti-bending portion 721 and a second anti-bending portion 722.

The reinforcing film 710 may be provided as a film having a predetermined thickness, and may be disposed on one surface of the circuit board 400. The reinforcing film 710 may be attached onto one surface of the circuit board 400 through an adhesive material such as an adhesive. The reinforcing film 710 may extend from one surface of the circuit board 400 to one surface of the inspection connector 630. The reinforcing film 710 extending from one surface of the circuit board 400 may extend onto one surface of the inspection connector 630 via one surface of the flexible film 620. The extending portion of the reinforcing film 710 may be attached onto one surface of the flexible film 620 and one surface of the inspection connector 630 through an adhesive material such as an adhesive.

The first anti-bending portion 721 may extend from one surface of the reinforcing film 710 in a direction crossing the direction in which the reinforcing film 710 extends. The first anti-bending portion 721 may be provided as a film having a predetermined thickness, and may extend from one surface of the reinforcing film 710 in the thickness direction of the reinforcing film 710. In other words, the first anti-bending portion 721 may extend from one surface of the reinforcing film 710 in the third direction D3. The first anti-bending portion 721 may be disposed on one surface of the reinforcing film 710, and may extend to one surface of the inspection connector 630 on one surface of the circuit board 400. In other words, the first anti-bending portion 721 may extend along one edge of the reinforcing film 710 on one surface of the reinforcing film 710.

The first anti-bending portion 721 may be formed to be folded based on a first boundary line BL1 that forms a boundary between the reinforcing film 710 and the first anti-bending portion 721.

The second anti-bending portion 722 may extend from one surface of the reinforcing film 710 in a direction crossing the direction in which the reinforcing film 710 extends. The second anti-bending portion 722 may be provided as a film having a predetermined thickness, and may extend from one surface of the reinforcing film 710 in the thickness direction of the reinforcing film 710. In other words, the second anti-bending portion 722 may extend from one surface of the reinforcing film 710 in the third direction D3. The second anti-bending portion 722 may be disposed on one surface of the reinforcing film 710, and may extend to one surface of the flexible film 620 on one surface of the circuit board 400. In other words, the second anti-bending portion 722 may extend along an opposing edge, which is opposite to the one edge, of the reinforcing film 710 on one surface of the reinforcing film 710.

The second anti-bending portion 722 may be formed to be folded based on a second boundary line BL2 that forms a boundary between the reinforcing film 710 and the second anti-bending portion 722. The second boundary line BL2 may be disposed in parallel with the first boundary line BL1. Since the second boundary line BL2 is disposed in parallel with the first boundary line BL1, the first anti-bending portion 721 and the second anti-bending portion 722 may be disposed in parallel with each other.

In such an embodiment, since the first anti-bending portion 721 and the second anti-bending portion 722 extend in a direction orthogonal to the reinforcing film 710, the first anti-bending portion 721 extends from the circuit board 400 toward the inspection connector 630 and the second anti-bending portion 722 extends from the circuit board 400 toward the flexible film 620, the reinforcing film 710 and the flexible film 620 attached to the reinforcing film 710 may be effectively prevented from being sagged.

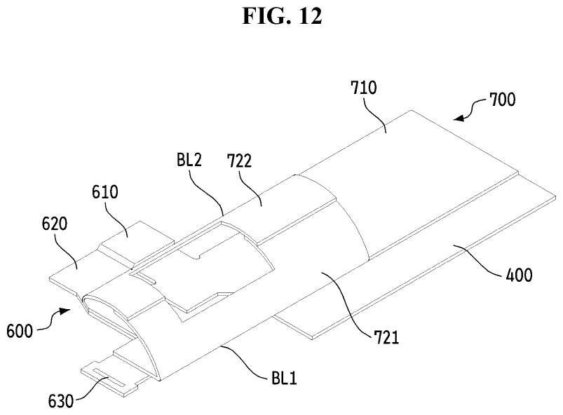

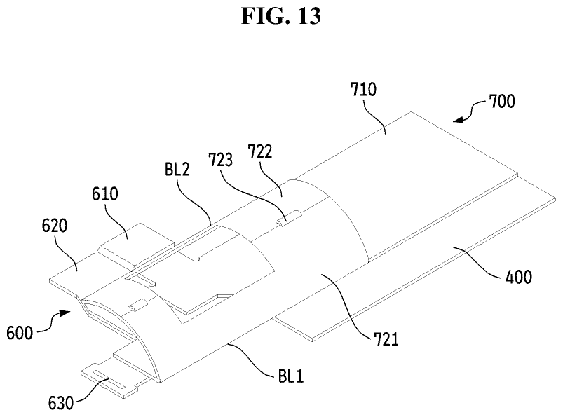

FIGS. 12 and 13 are perspective views illustrating a state that the circuit board 400, the connector assembly 600 and the reinforcing member 700 of the display device 10 according to another embodiment of the disclosure are connected.

Referring to FIGS. 12 and 13, the reinforcing member 700 of the display device 10 according to another embodiment of the disclosure may be disposed on one surface of the connector assembly 600 and the circuit board 400 to effectively prevent the inspection connector 630 from being sagged in the third direction D3. The reinforcing member 700 may include a reinforcing film 710, a first anti-bending portion 721 and a second anti-bending portion 722.

The reinforcing film 710 may be provided as a film having a predetermined thickness, and may be disposed on one surface of the circuit board 400. The reinforcing film 710 may be attached onto one surface of the circuit board 400 through an adhesive material such as an adhesive. The reinforcing film 710 may extend from one surface of the circuit board 400 to one surface of the inspection connector 630. The reinforcing film 710 extending from one surface of the circuit board 400 may extend onto one surface of the inspection connector 630 via one surface of the flexible film 620. The extending portion of the reinforcing film 710 may be attached onto one surface of the flexible film 620 and one surface of the inspection connector 630 through an adhesive material such as an adhesive.

The first anti-bending portion 721 may extend from one surface of the reinforcing film 710 in a direction crossing the direction in which the reinforcing film 710 extends. The first anti-bending portion 721 may be provided as a film having a predetermined thickness, and may extend from one surface of the reinforcing film 710 toward the other side of the reinforcing film 710. In other words, the first anti-bending portion 721 may extend from one edge of the reinforcing film 710 in the other side direction of the reinforcing film 710. The first anti-bending portion 721 may be disposed on one surface of the reinforcing film 710, and may extend to one surface of the inspection connector 630 on one surface of the circuit board 400. The first anti-bending portion 721 may extend along one edge of the reinforcing film 710 on one surface of the reinforcing film 710.

The first anti-bending portion 721 may be formed to be folded based on a first boundary line BL1 that forms a boundary between the reinforcing film 710 and the first anti-bending portion 721.

The second anti-bending portion 722 may extend from one surface of the reinforcing film 710 in a direction crossing the direction in which the reinforcing film 710 extends. The second anti-bending portion 722 may be provided as a film having a predetermined thickness, and may extends from one surface of the reinforcing film 710 toward one side of the reinforcing film 710. In other words, the second anti-bending portion 722 may extend from an opposing edge of the reinforcing film 710 in one side direction of the reinforcing film 710. The second anti-bending portion 722 may be disposed on one surface of the reinforcing film 710, and may extend to one surface of the flexible film 620 on one surface of the circuit board 400. The second anti-bending portion 722 may extend along an opposing edge of the reinforcing film 710 on one surface of the reinforcing film 710.

The second anti-bending portion 722 may be formed to be folded based on a second boundary line BL2 that forms a boundary between the reinforcing film 710 and the second anti-bending portion 722. The second boundary line BL2 may be disposed in parallel with the first boundary line BL1. Since the second boundary line BL2 is disposed in parallel with the first boundary line BL1, the first anti-bending portion 721 and the second anti-bending portion 722 may be disposed in parallel with each other.

Referring to FIG. 12, an extended end portion of the first anti-bending portion 721 and an extended end portion of the second anti-bending portion 722 may overlap each other. The extended end portion of the first anti-bending portion 721 and the extended end portion of the second anti-bending portion 722 may be adhered to each other through an adhesive material such as an adhesive.

The portion where the extended end portion of the first anti-bending portion 721 and the extended end portion of the second anti-bending portion 722 overlap each other may be spaced apart from one surface of the reinforcing film 710. In other words, the first anti-bending portion 721 and the second anti-bending portion 722 may be formed in an arch shape formed to be convex in the thickness direction of the reinforcing film 710.

Referring to FIG. 13, the extended end portion of the first anti-bending portion 721 and the extended end portion of the second anti-bending portion 722 may be in contact with each other. A fastening portion 723 may be disposed between the extended end portion of the first anti-bending portion 721 and the extended end portion of the second anti-bending portion 722 to fasten the extended end portion of the first anti-bending portion 721 and the extended end portion of the second anti-bending portion 722 to each other.

The portion where the extended end portion of the first anti-bending portion 721 is in contact with the extended end portion of the second anti-bending portion 722 may be spaced apart from one surface of the reinforcing film 710. In other words, the first anti-bending portion 721 and the second anti-bending portion 722 may be formed in an arch shape formed to be convex in the thickness direction of the reinforcing film 710.

In such an embodiment, since the first anti-bending portion 721 and the second anti-bending portion 722 are fastened to each other by extending in a direction crossing the reinforcing film 710, the first anti-bending portion 721 extends from the circuit board 400 toward the inspection connector 630 and the second anti-bending portion 722 extends from the circuit board 400 toward the flexible film 620, the reinforcing film 710, the flexible film 620 attached to the reinforcing film 710 and the inspection connector 630 may be effectively prevented from being sagged.

The display device according to one embodiment of the present disclosure can be applied to various electronic devices. The electronic device according to the one embodiment of the present disclosure includes the display device described above, and may further include modules or devices having additional functions in addition to the display device.

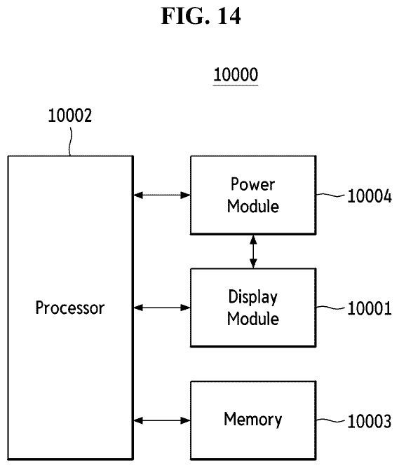

FIG. 14 is a block diagram of an electronic device according to one embodiment of the present disclosure.

Referring to FIG. 14, the electronic device 10000 according to one embodiment of the present disclosure may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), and a controller.

The memory 10003 may store data information necessary for the operation of the processor 10002 or the display module 10001. When the processor 10002 executes an application stored in the memory 10003, an image data signal and/or an input control signal is transmitted to the display module 10001, and the display module 10001 can process the received signal and output image information through a display screen.

The power module 10004 may include a power supply module such as, for example a power adapter or a battery, and a power conversion module that converts the power supplied by the power supply module to generate power necessary for the operation of the electronic device 10000.

At least one of the components of the electronic device 10000 according to the one embodiment of the present disclosure may be included in the display device according to the embodiments of the present disclosure. In addition, some modules of the individual modules functionally included in one module may be included in the display device, and other modules may be provided separately from the display device. For example, the display device may include the display module 10001, and the processor 10002, the memory 10003, and the power module 10004 may be provided in the form of other devices within the electronic device 10000 other than the display device.

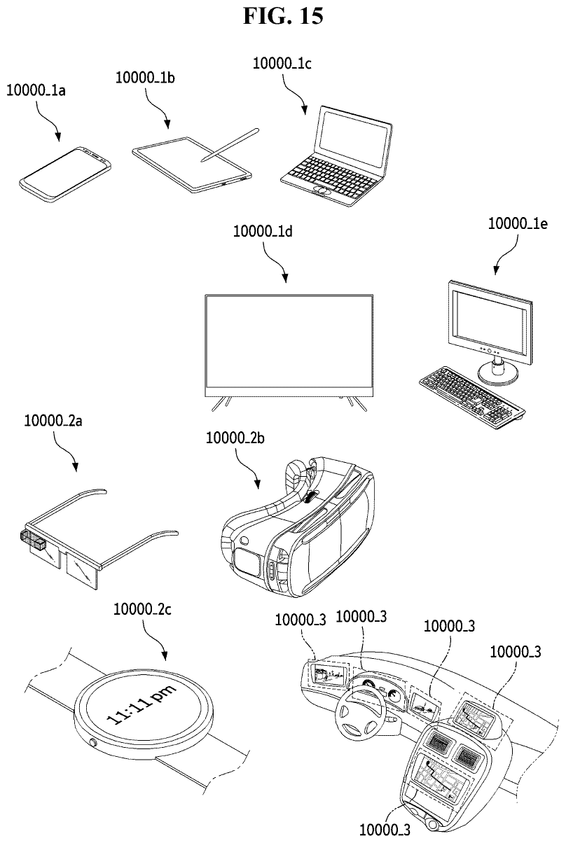

FIG. 15 is a schematic diagram of an electronic device according to various embodiments of the present disclosure.

Referring to FIG. 15, various electronic devices to which display devices according to embodiments of the present disclosure are applied may include not only image display electronic devices such as a smart phone 10000_1a, a tablet PC (personal computer) 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a CID (Center Information Display) and a room mirror display arranged on a dashboard, center fascia, and dashboard of an automobile.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel;
a circuit board electrically connected to the display panel;
a connector assembly electrically connected to the circuit board; and
a reinforcing member disposed on the circuit board,
wherein the reinforcing member includes:
a reinforcing film extending from one surface of the circuit board to one surface of the connector assembly; and
an anti-bending portion extending from one surface of the reinforcing film in a direction crossing a direction in which the reinforcing film extends.

2. The display device of claim 1, wherein the anti-bending portion extends in a direction orthogonal to the direction in which the reinforcing film extends.

3. The display device of claim 1, wherein the anti-bending portion is folded based on a boundary line between the reinforcing film and the anti-bending portion.

4. The display device of claim 3, wherein the anti-bending portion is folded to overlap the reinforcing film.

5. The display device of claim 3, wherein the anti-bending portion includes:
a first anti-bending portion folded based on a first boundary line; and
a second anti-bending portion folded based on a second boundary line crossing the first boundary line.

6. The display device of claim 5, wherein the first boundary line and the second boundary line are defined along one edge of the reinforcing film.

7. The display device of claim 1, wherein the anti-bending portion includes a first anti-bending portion and a second anti-bending portion,
the first anti-bending portion extends from one edge of one surface of the reinforcing film, and
the second anti-bending portion extends from an opposing edge of the one surface of the reinforcing film.

8. The display device of claim 7, wherein the first anti-bending portion is disposed along the one edge of the one surface of the reinforcing film, and
the second anti-bending portion is disposed along the opposing edge of the one surface of the reinforcing film.

9. The display device of claim 7, wherein the first anti-bending portion and the second anti-bending portion are disposed in parallel with each other.

10. The display device of claim 7, wherein the first anti-bending portion extends toward an opposing side of the reinforcing film, and
the second anti-bending portion extends toward one side of the reinforcing film.

11. The display device of claim 10, wherein an extended end portion of the first anti-bending portion and an extended end portion of the second anti-bending portion overlap each other.

12. The display device of claim 11, wherein a portion where an extended end portion of the first anti-bending portion and an extended end portion of the second anti-bending portion overlap each other is spaced apart from the one surface of the reinforcing film.

13. The display device of claim 10, wherein an extended end portion of the first anti-bending portion and an extended end portion of the second anti-bending portion are in contact with each other, and
a fastening portion, which fastens an extended end portion of the first anti-bending portion and an extended end portion of the second anti-bending portion to each other, is disposed at a portion where the extended end portion of the first anti-bending portion and the extended end portion of the second anti-bending portion are in contact each other.

14. A display device comprising:
a display panel;
a circuit board electrically connected to the display panel, wherein the circuit board includes a connection terminal;
a connector assembly including a connection connector connected to the connection terminal and an inspection connector connected to the connection connector; and
a reinforcing member disposed on the circuit board,
wherein the reinforcing member includes:
a reinforcing film disposed on one surface of the circuit board and one surface of the inspection connector; and
an anti-bending portion disposed on one surface of the reinforcing film and extending from the one surface of the circuit board to the one surface of the inspection connector.

15. The display device of claim 14, wherein the anti-bending portion extends from the one surface of the reinforcing film in a thickness direction of the reinforcing film.

16. The display device of claim 15, wherein the anti-bending portion folded based on a boundary line between the reinforcing film and the anti-bending portion.

17. The display device of claim 16, wherein the anti-bending portion is folded to overlap the reinforcing film.

18. The display device of claim 16, wherein the anti-bending portion includes
a first anti-bending portion folded based on a first boundary line; and
a second anti-bending portion folded based on a second boundary line crossing the first boundary line.

19. The display device of claim 15, wherein the anti-bending portion includes a first anti-bending portion and a second anti-bending portion,
the first anti-bending portion extends from one edge of the one surface of the reinforcing film, and
the second anti-bending portion extends from an opposing edge of the one surface of the reinforcing film.

20. The display device of claim 19, wherein the first anti-bending portion extends toward an opposing side of the reinforcing film,
the second anti-bending portion extends toward one side of the reinforcing film, and
an extended end portion of the first anti-bending portion and an extended end portion of the second anti-bending portion overlap each other, or are in contact with each other.

21. A electronic device comprising:
a display panel;
a circuit board electrically connected to the display panel;
a connector assembly electrically connected to the circuit board; and
a reinforcing member disposed on the circuit board,
wherein the reinforcing member includes:
a reinforcing film extending from one surface of the circuit board to one surface of the connector assembly; and
an anti-bending portion extending from one surface of the reinforcing film in a direction crossing a direction in which the reinforcing film extends.
